(19) United States
(12) Patent Application Publication
(10) Pub. No.: US 2025/0201661 A1
(43) Pub. Date: Jun. 19, 2025

(54) METHODS AND APPARATUS TO IMPROVE DISSIPATION OF HEAT FROM INTEGRATED CIRCUIT PACKAGES USING CARBON NANOTUBES

(71) Applicant: Intel Corporation, Santa Clara, CA (US)

(72) Inventors: Joachim Stahl, Miesbrunn (DE); Harald Gossner, Riemerling (DE); Florian Kretzschmar, Munich (DE); Martin Ostermayr, Woerth (DE)

(73) Assignee: Intel Corporation, Santa Clara, CA (US)

(21) Appl. No.: 19/063,598

(22) Filed: Feb. 26, 2025

(51) Int. Cl. H01L 23/373; B82Y 30/00; H01L 23/00; H01L 23/538; H01L 25/07

(52) U.S. Cl. CPC H01L 23/3736; B82Y 30/00; H01L 23/5385; H01L 24/13; H01L 24/14; H01L 24/16; H01L 25/072; H01L 2224/13193; H01L 2224/14051; H01L 2224/14519; H01L 2224/16227; H01L 2924/15165

(57) ABSTRACT

Systems, apparatus, articles of manufacture, and methods to dissipate heat within and/or from integrated circuit packages using carbon nanotubes are disclosed. An example integrated circuit package includes: a first metal layer; a second metal layer; and an array of carbon nanotubes extending from the first metal layer toward the second metal layer.

### BACKGROUND

The demand for greater computing power and faster computing times continues to grow. This has led to smaller transistors being constructed more closely together at higher densities within integrated circuits. This results in more power being used for a given area of an integrated circuit and an associated increase in heat produced the given area of the integrated circuit.

### BRIEF DESCRIPTION OF THE DRAWINGS

FIG. 1 illustrates an example integrated circuit (IC) package constructed in accordance with teachings disclosed herein.

FIG. 2 is a cross-sectional top view (e.g., a plan view) of a portion of the first metal layer of the example interposer of FIG. 1 taken along the line 2-2 associated with the first inset image of FIG. 1.

FIG. 3 is a cross-sectional top view (e.g., a plan view) of a portion of the third and fourth metal layers of the first semiconductor die of FIG. 1 taken along the line 3-3 associated with the second inset image of FIG. 1.

FIG. 4 is a top view of a wafer including dies that may be included in an IC package constructed in accordance with teachings disclosed herein.

FIG. 5 is a cross-sectional side view of an IC device that may be included in an IC package constructed in accordance with teachings disclosed herein.

FIG. 6 is a cross-sectional side view of an IC device assembly that may include an IC package constructed in accordance with teachings disclosed herein.

FIG. 7 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

The demand for greater computing power and faster computing times continues to grow. This has led to smaller transistors being constructed more closely together at higher densities. As a result, the power per area in computing and power chips that needs to be dissipated to avoid overheating continues to rise. Removing this heat from inside an integrated circuit (IC) (e.g., a semiconductor chip) to the outside (e.g., package) is becoming increasingly difficult and often limits the IC's maximum performance. In known IC packages, such heat is typically transferred from the transistors to an exterior surface of the packages through the metallization (e.g., metal layers and intervening metal vias extending therebetween) in the package. Metal in known packages is the primary mechanism by which heat is transferred to an exterior surface for dissipation because the dielectric material between the metal is usually a relatively poor thermal conductor.

Examples disclosed herein incorporate carbon nanotubes into IC packages to enhance heat removal away from the active silicon transistor level. In some examples, carbon nanotubes are provided directly within a semiconductor (e.g., silicon) die or chip containing active transistors from which heat is to be dissipated. Additionally or alternatively, in some examples, carbon nanotubes are provided within an underlying substrate on which the semiconductor die is mounted. For instance, in some examples, the underlying substrate is a semiconductor-based (e.g., a silicon-based) interposer. In other examples, the underlying substrate is an epoxy-based package substrate. Additionally or alternatively, in some examples, carbon nanotubes are provided between a semiconductor die and the underlying substrate on which the die is mounted. In some examples, the carbon nanotubes provide thermal coupling between adjacent layers of metal, thereby enhancing the heat transfer through an associated package.

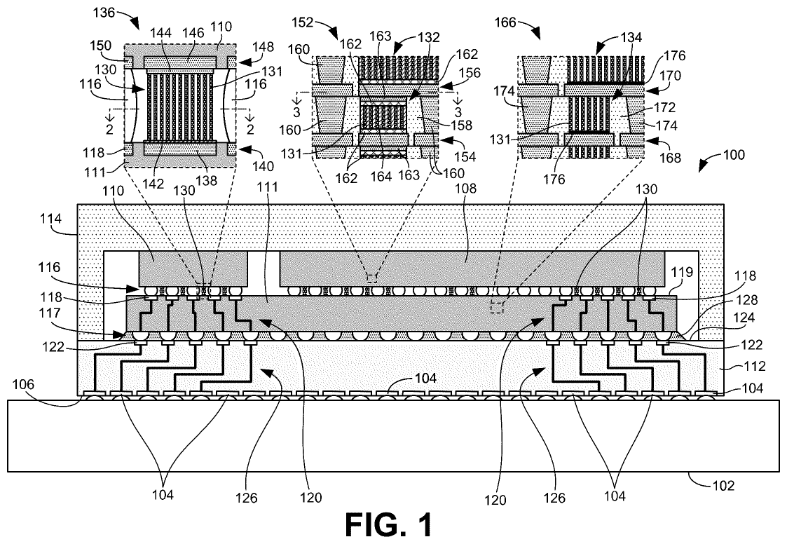

FIG. 1 illustrates an example integrated circuit (IC) package 100 constructed in accordance with teachings disclosed herein. In the illustrated example, the IC package 100 is electrically coupled to an underlying substrate 102 via an array of contacts 104 on a package mounting surface 106 (e.g., a bottom surface, an external surface) of the package. In some examples, the substrate 102 can be implemented by a printed circuit board (PCB) or a package substrate (e.g., the IC package 100 is part of another larger package). In the illustrated example, the contacts 104 are represented as pads or lands. However, in some examples, the IC package 100 may include balls, pins, and/or any other type(s) of contacts, in addition to or instead of the pads or lands shown, to enable the electrical coupling of the IC package 100 to the substrate 102. In this example, the package 100 includes two semiconductor dies 108, 110 (e.g., silicon dies), sometimes also referred to as chips or chiplets, that are mounted on (e.g., supported by) a silicon-based interposer 111. The interposer 111 is, in turn, mounted on (e.g., supported by) a package substrate 112. In some examples, the interposer 111 is silicon-based. In such examples, the interposer 111 can also be referred to as a semiconductor die or semiconductor chip. In other examples, the interposer 11 is an organic epoxy-based interposer.

As shown in the illustrated example, the semiconductor dies 108, 110 and the interposer 111 are enclosed by a package lid 114 (e.g., a mold compound, an integrated heat spreader (IHS)). In some examples, the package lid 114 is omitted, thereby leaving the semiconductor dies 108, 110 and the interposer 111 exposed or bare. In some examples, the interposer 111 is omitted and the semiconductor dies 108, 110 are mounted directly to the package substrate 112.

While the example IC package 100 of FIG. 1 includes two dies 108, 110, in other examples, the IC package 100 may have only one die or more than two dies. In some examples, one of the dies 108, 110 (or a separate die) is embedded in the package substrate 112. The dies 108, 110 can provide any suitable type of functionality (e.g., data processing, memory storage, etc.). In some examples, one or both of the dies 108, 110 are implemented by a die package including multiple dies arranged in a stacked formation. For example, the die 110 can include a stack of Dynamic Random Access Memory (DRAM) dies arranged on top of a memory controller die to form a memory die stack.

As shown in the illustrated example, each of the dies 108, 110 is electrically and mechanically coupled to the interposer 111 via corresponding arrays of first interconnects 116. Further, the interposer 111 is electrically and mechanically coupled to the package substrate 112 via an array of second interconnects 117. In FIG. 1, the first and second interconnects 116, 117 are shown as bumps. In some examples, the interconnects 116, 117 can include solder joints, micro bumps, combinations of metallic (e.g., copper) pillars and solder, etc. In other examples, the interconnects 116, 117 may include directly bonded or “hybrid bonded” metallic interconnects. In other examples, the interconnects 116, 117 may be any other type of electrical connection in addition to or instead of the bumps shown (e.g., balls, pins, pads, pillars, wire bonding, etc.). In some examples, as represented in FIG. 1, the first interconnects 116 are smaller and/or closer together (e.g., spaced at a smaller pitch) than the second interconnects 117. The electrical connections between the dies 108, 110 and the interposer 111 (e.g., the first interconnects 116) and between the interposer 111 and the package substrate 112 (e.g., the second interconnects 117) are sometimes referred to as first level interconnects. By contrast, the electrical connections between the IC package 100 and the substrate 102 (e.g., the contacts 104) are sometimes referred to as second level interconnects.

The first and second interconnects 116, 117 enabling electrical coupling of the dies 108, 110 with the substrate 102. More particularly, as shown in FIG. 1, the example first interconnects 116 are physically connected and electrically coupled to first contact pads 118 on a die mounting surface 119 (e.g., an upper surface, a top surface, etc.) of the interposer 111. The first contact pads 118 on the die mounting surface 119 of the interposer 111 are electrically coupled to the second interconnects 117 on the opposite side of the interposer 111 via first internal interconnects 120 within the interposer 111. Further, as shown in the illustrated examples, the second interconnects 117 are physically connected and electrically coupled to second contact pads 122 on a mounting surface 124 (e.g., an upper surface, a top surface, etc.) of the package substrate 112. The second contact pads 122 on the mounting surface 124 of the package substrate 112 are electrically coupled to the contacts 104 on the package mounting surface 106 (e.g., the bottom, external surface) of the package substrate 112 (e.g., a surface opposite the mounting surface 124) via second internal interconnects 126 within the package substrate 112. As a result, there is a continuous electrical signal path between the first interconnects 116 of the dies 108, 110 and the contacts 104 mounted to the substrate 102 that pass through the first contact pads 118, the first internal interconnects 120, the second interconnects 117, and the second internal interconnects 126.

In some examples, an underfill material 128 is disposed between the interposer 111 and the package substrate 112 around and/or between the second interconnects 117. Additionally or alternatively, in some examples, the underfill material 128 is disposed between one or more of the dies 108, 110 and the interposer 111. In other examples, the underfill material 128 is omitted. In some examples, the mold compound used for the package lid 114 is used as an underfill material that surrounds the first interconnects 116 and/or the second interconnects 117.

In some examples, the IC package 100 includes additional passive components, such as surface-mount resistors, capacitors, and/or inductors disposed on the package mounting surface 106 of the package substrate 112 and/or the die mounting surface 124 of the package substrate 112.

In the illustrated example of FIG. 1, the semiconductor dies 108, 110 include active semiconductor components (e.g., transistors) that generate heat during operation. To avoid overheating, such heat needs to be dissipated. In known IC packages, heat is primarily transferred away from transistors through the metallization inside the dies 108, 110 and other metal that is thermally coupled to the metallization inside the dies 108, 110. That is, internal interconnects within the dies 108, 110 conduct heat away from transistors. This heat can then be transferred away from the dies 108, 110 through the first interconnects 116 to the contact pads 118 and the associated first internal interconnects 120 within the interposer 111 and on through the second internal interconnects 126 in the package substrate 112. In other words, the metal throughout the IC package 100 facilitates the spread of heat throughout the entire package and externally, thereby reducing the creation of localized hotspots that would otherwise negatively impact the operation of the dies 108, 110 (e.g., negatively impact the performance, efficiency, and/or reliability). This heat transfer is primarily achieved through the metal because metal is typically much more thermally conductive than the intermetal dielectric material(s) between different portions of the metal.

In examples disclosed herein, heat transfer between different regions of the example IC package 100 is facilitated by arrays of carbon nanotubes (also referred to herein as carbon nanotube pincushions) positioned between the different portions of the metal throughout the IC package 100. More particularly, as shown in the illustrated example of FIG. 1, the IC package 100 includes one or more first arrays 130 of carbon nanotubes 131 positioned between adjacent ones of the first interconnects 116 (e.g., between adjacent bumps connecting the dies 108, 110 and the interposer 111). More particularly, in some examples, a majority of the carbon nanotubes 131 are arranged substantially parallel (e.g., within 10 degrees of parallel) to one other and substantially perpendicular (e.g., within 10 degrees of perpendicular) to a plane along which the first interconnects 116 are distributed. In some examples, the orientation of the nanotubes 131 corresponds to a direction along which heat is to travel to facilitate thermal dissipation. Thus, in this example, the first arrays 130 of carbon nanotubes 131 are oriented to facilitate heat to travel from the semiconductor dies 108, 110 (where the heat is generated) towards and/or into the interposer 111. In this manner, heat dissipation is not limited to passing through the first interconnects 116 to be spread out into the interposer 111 (and/or beyond).

In some examples, a separate first array 130 of carbon nanotubes 131 is positioned between each adjacent pair of first interconnects 116 as shown in connection with the second die 110. In other examples, the first arrays 130 of carbon nanotubes 131 are located between some (but not all) adjacent pairs of the first interconnects 116 as shown in connection with the first die 108. In some examples, as discussed above, the interconnects 116 are surrounded by an underfill material (e.g., similar to the underfill material 128 underneath the interposer 111). In some such examples, the underfill material surrounds the first arrays 130 of carbon nanotubes 131). That is, in some examples, a dielectric material is positioned between the carbon nanotube arrays 130 and the adjacent bumps of the first interconnects 116.

Further, as shown in the illustrated example, the IC package 100 includes one or more second arrays 132 of carbon nanotubes 131 within at least one of the first die 108 or the second die 110, and one or more third arrays 134 of carbon nanotubes 131 within the interposer 111. In some examples, some or all of the first carbon nanotube arrays 130 are omitted. In some examples, some or all of the second carbon nanotube arrays 132 are omitted. In some examples, some or all of the third carbon nanotube arrays 134 are omitted. Additionally or alternatively, in some examples, one or more arrays of carbon nanotubes can be positioned between adjacent ones of the second interconnects 117 (e.g., between the interposer 111 and the package substrate 112), and/or within the package substrate 112. In other words, the example arrays of carbon nanotubes disclosed herein can be at any suitable location within the example IC package 100. Such locations are not limited to the particular locations shown in the illustrated examples. As with the nanotubes 131 in the first arrays 130, the nanotubes 131 in the second and third arrays 132, 134 are arranged substantially parallel (e.g., within 10 degrees of parallel) to one other and substantially perpendicular (e.g., within 10 degrees of perpendicular) to the adjacent metal layers between which the nanotubes 131 extend.

FIG. 1 includes a first inset image 136 showing an enlarged view of one of the first arrays 130 of carbon nanotubes 131 between adjacent ones of the first interconnects 116 electrically coupling the second die 110 to the interposer 111. In this example, the first array 130 includes individual carbon nanotubes 131 that extend generally orthogonal to a first conductive pad 138 (e.g., a metal pad) that is part of the same metal layer 140 (e.g., a first metal layer, a first metallization layer) as the contact pads 118 to which the first interconnects 116 are coupled. Thus, in some examples, the first conductive pad 138 is composed of the same material (e.g., copper) as the contact pads 118. In this example, the conductive pad 138 is electrically isolated from the contact pads 118 on either side. However, in some examples, the conductive pad 138 can be connected to (e.g., is an extension of) at least one of the contact pads 118 in the first metal layer 140.

In some examples, the carbon nanotubes 131 are fabricated (e.g., grown) in situ on the surface of the first conductive pad 138. In some such examples, in situ growth of the carbon nanotubes 131 is facilitated by first applying a seed layer 142 to the surface of the first conductive pad 138. In some examples, the seed layer 142 includes nickel. In some examples, the resulting bunch of nanotubes 131 (e.g., a carbon nanotube pincushion or first array 130) are densely packed together to produce a substantially solid (e.g., voids or gaps are limited to less than 5%) and substantially pure mass of carbon with little to no space between adjacent nanotubes 131 (e.g., directly abutting). That is, in some examples, the carbon nanotubes 131 are much closer together than the spacing shown in the illustrated example for purposes of clarity and explanation. As used in this context, “substantially solid” means gaps or voids between adjacent nanotubes 131 are limited to less than 30% of the total volume of the associated carbon nanotube pincushion. In some examples, the volume of gaps or voids between adjacent nanotubes 131 can be significantly less than 30% (e.g., less than 20%, less than 15%, less than 10%, less than 5%, etc.). Further, as used in this context, “substantially pure” means there is less than 5 wt % of trace elements other than carbon within the carbon nanotube pincushions. In some examples, the amount of trace elements can be significantly less than 5 wt % (e.g., less than 3 wt %, less than 2 wt %, less than 1 wt %, etc.).

As shown in the first inset image 136, the example first carbon nanotube arrays 130 includes a cap 144 at the distal ends of the nanotubes 131 opposite the seed layer 142. In some examples, the cap 144 provides structural support to the nanotubes 131 to help hold them together and facilitate further fabrication processes associated with the first carbon nanotube arrays 130. In some examples, the cap 144 provides thermal coupling between the nanotubes 131 and a second conductive pad 146 (e.g., a metal pad) in the die 110. As shown in the illustrated example, the second conductive pad 146 is part of the same metal layer 148 (e.g., a second metal layer, a second metallization layer) as contact pad 150 to which the first interconnects 116 are coupled opposite the contact pads 118 of the interposer 111. Thus, in some examples, the second conductive pad 146 includes and/or is composed of the same material (e.g., copper) as the contact pads 150. In this example, the conductive pad 146 is electrically isolated from the contact pads 150 on either side. However, in some examples, the conductive pad 146 can be connected to (e.g., is an extension of) at least one of the contact pads 150 in the second metal layer 148 of the die 110. In some examples, the cap 144 includes at least one of a dielectric material or a polymer. Additionally or alternatively, in some examples, the cap 144 includes metal. In some such examples, the metal in the cap 144 is the same material used in the second conductive pad 146 of the second metal layer 148.

Carbon nanotubes are thermally conductive and, therefore, can relatively easily transfer heat. Thus, the first array 130 of carbon nanotubes 131 serves as an additional means for dissipating heat throughout the IC package 100. More particularly, in some examples, the conductive pads 138, 146 at either end of the nanotubes 131 are thermally coupled to additional metal at different metallization layers in the semiconductor die 110 and/or in the interposer 111. As a result, in this example, heat is not limited primarily to the metal interconnects 116 to pass heat from the die 110 to the interposer 111 (as is the case with known IC packages), but heat can also be transferred by way of the carbon nanotubes 131 for improved thermal dissipation relative to the poor heat transfer provided by intermetal dielectric materials used at the same locations in known packages.

FIG. 1 includes a second inset image 152 showing an enlarged view of a stack of the second arrays 132 of carbon nanotubes 131. More particularly, in this example, two different metal layers 154, 156 (e.g., third and fourth metal layers, metallization layers) are shown with a second carbon nanotube arrays 132 extending through a dielectric material 158 (e.g., a dielectric layer) disposed between the third and fourth metal layers 154, 156. Further, in this example, additional second carbon nanotube arrays 132 are provided below the third metal layer 154 and above the fourth metal layer 156. In this example, the second arrays 132 of carbon nanotubes 131 are constructed in substantially the same way as the first array 130 of carbon nanotubes 131 discussed in connection with the first inset image 136 except as otherwise noted. Rather than being adjacent to first level interconnects (e.g., the interconnects 116) between the dies 108, 110 and the interposer 111, in the example shown in the second inset image 152, the nanotubes 131 are positioned adjacent metal vias 160 in a space between the third and fourth metal layers 154, 156 inside the first die 108. In some examples, the second arrays 132 of carbon nanotubes 131 are added during a front end of line (FEOL) fabrication processing of the semiconductor die 108 (e.g., during the fabrication processing of transistors on a semiconductor substrate). Additionally or alternatively, in some examples, the second arrays 132 of carbon nanotubes 131 are added during a back end of line (BEOL) fabrication processing of the semiconductor die 108 (e.g., after fabrication of the transistors is complete). In some examples, the second arrays 132 of carbon nanotubes 131 are added onto the backside of the semiconductor die 108 such as when the semiconductor die 108 includes backside power delivery. Additionally or alternatively, in some examples, the second arrays 132 of carbon nanotubes 131 are added onto the frontside of the semiconductor die 108 either in connection with power delivery metallization (e.g., when there is no backside delivery) or in connection with signaling metallization (e.g., when there is backside power delivery).

In some examples, as shown in the second inset image 152, at least one end of the nanotubes 131 are adjacent to an electrically insulating layer 162 (e.g., a non-conductive cap, a dielectric material). In some examples, the electrically insulating layer 162 prevents electrical current from being conducted along the nanotubes 131 between the different metal layers 154, 156. Although two electrically insulating layers 162 are shown (e.g., one at each end of the nanotubes 131), in other examples, only one insulating layer 162 is employed at one end of the nanotubes 131 and the other insulating layer 162 is omitted. Furthermore, in some examples, both insulating layers 162 can be omitted. In some examples, the insulating layers 162 are omitted because there is no concern with the nanotubes 131 providing an electrically conductive path between the metal layers 154, 156. Additionally or alternatively, in some examples, the insulating layers 162 are omitted because the second array(s) 132 of carbon nanotubes 131 are fabricated to be electrically insulating. Whether or not carbon nanotubes are electrically conductive or electrically insulative is controlled based on the fabrication processes, parameters, and/or conditions during nanotube formation and/or growth. Additionally or alternatively, in some examples, after the second array(s) 132 of carbon nanotubes 131 are fabricated (e.g., grown), the nanotubes 131 are rendered electrically insulative by implementing a burning process to fuse any metallic nanotubes in the array.

The example second array(s) 132 of carbon nanotubes 131 shown in the second inset image 152 include a cap 163 similar to the example cap 144 discussed above in connection with the first inset image 136. In this example, the cap 163 is a metal cap that is between the insulating layer 162 and the fourth metal layer 156. In other examples, the metal cap 163 is in direct contact with ends of the nanotubes 131 with the insulating layer 162 between the cap 163 and the fourth metal layer 156. In other examples, the cap 163 is omitted.

Another difference between the first carbon nanotube array 130 in the first inset image 136 and the second carbon nanotube arrays 132 in the second inset image 152 is the inclusion of a polymer material 164 between adjacent ones of the nanotubes 131. Whereas the first array 130 of carbon nanotubes 131 is grown in situ on the first conductive pad 138 (e.g., from the seed layer 142 disposed thereon), the second arrays 132 of carbon nanotubes 131 are fabricated by depositing a polymer solution containing the polymer material 164 and the (already fabricated) nanotubes 131 onto an underlying surface (e.g., either within an opening in the layer of the dielectric material 158 or across the metal layer 154 prior to adding the layer of the dielectric material 158). In some such examples, after being deposited, the polymer solution is cured into a final (e.g., substantially solid) structure. In some examples, during the curing process, some or all of the polymer material 164 may be removed so that only the nanotubes 131 remain. However, in some examples, at least some trace amounts of the polymer material 164 are retained in the final structure. In some examples, depending on the particular fabrication processes involved, the nanotubes 131 may not all be oriented in the same direction and/or may not be oriented substantially orthogonal to the associated metal layers 154, 156 at either end of the nanotubes 131 as shown in the second inset image 152.

FIG. 1 includes a third inset image 166 showing an enlarged view of a stack of the third arrays 134 of carbon nanotubes 131. More particularly, in this example, two different metal layers 168, 170 (e.g., fifth and sixth metal layers, metallization layers) are shown with a third array 134 of carbon nanotubes 131 extending through a dielectric material 172 disposed between the fifth and sixth metal layers 168, 170. Further, in this example, additional third arrays 134 of carbon nanotubes 131 are provided below the fifth metal layer 154 and above the sixth metal layer 156. In this example, the third carbon nanotube arrays 134 are constructed in substantially the same way as the first carbon nanotube array 130 discussed in connection with the first inset image 136 except as otherwise noted. Rather than being adjacent to first level interconnects (e.g., the interconnects 116) between the dies 108, 110 and the interposer 111, in the example shown in the third inset image 166, the nanotubes 131 are positioned adjacent metal vias 174 in a space between the metal layers 168, 170 inside the interposer 111.

In this example, the third arrays 134 of carbon nanotubes 131 shown in the third inset image 166 are fabricated (e.g., grown) on a separate substrate and then subsequently transferred (e.g., via a pick and place operation) to the position shown in FIG. 1. In some such examples, the transferred third array(s) 134 of carbon nanotubes 131 are attached to the underlying metal layers 168, 170 with an adhesive material 176. Although not shown in FIG. 1, in some such examples, at least some of the substrate on which the nanotubes 131 are grown can also be transferred onto the metal layers 168, 170.

The example arrays 134 of carbon nanotubes 131 shown in the third inset image 166 of FIG. 1 differ from the other example arrays 130, 132 in that the nanotubes 131 are not capped at their ends distal to the underlying metal layer 168. That is, unlike what is shown in the first and second inset images 136, 152, there is no cap 144, 163 in the example shown in the third inset image 166. Instead, the nanotubes 131 directly contact (e.g., abut) the metal layer 170 immediately above the associated third array 134 of carbon nanotubes 131.

Each of the inset images 136, 152, 166 shown in FIG. 1 illustrate different features and/or structures of example carbon nanotube pincushions disclosed herein that may be achieved through different fabrication processes. However, any of the features, structures, and/or associated fabrication processes can be used in combination with and/or instead of the features, structures, and/or associated fabrication processes shown and described in connection with any given carbon nanotube array 130, 132, 134. Thus, in some examples, the first carbon nanotube array 130 shown in the first inset image 136 may include one or more insulating layers 162 and/or a polymer material 164 as shown and described in connection with the second inset image 152. Additionally or alternatively, in some examples, the first carbon nanotube array 130 may omit the seed layer 142 and/or may omit the cap 144. Additionally or alternatively, in some examples, the first carbon nanotube array 130 may include an adhesive material 176 as shown and described in connection with the third inset image 166. Similarly, the second carbon nanotube arrays 132 shown in the second inset image 152 may include the seed layer 142 and/or the adhesive material 176 as shown and described in connection with the first and/or third inset images 136, 166. Additionally or alternatively, the second carbon nanotube arrays 132 may omit the insulating layer(s) 162, the cap 163, and/or the polymer material 164 as shown and described in connection with the first and/or third inset images 136, 166. Likewise, the third carbon nanotube arrays 134 shown in the third inset image 166 may include the seed layer 142, the cap 144, 163, the insulating layer(s) 162, and/or the polymer material 164 as shown and described in connection with the first and/or second inset images 136, 166. Additionally or alternatively, the third carbon nanotube arrays 134 may omit the adhesive material 176. Further, any of the carbon nanotube arrays 130, 132, 134 can be implemented with either electrically conductive nanotubes 131 or electrically insulative nanotubes 131.

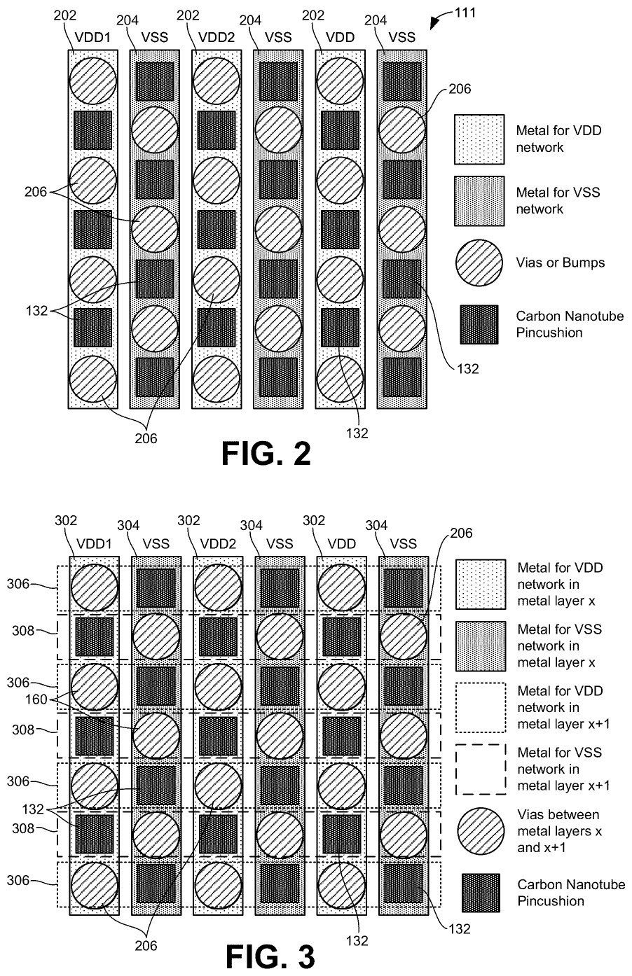

FIG. 2 is a cross-sectional top view (e.g., a plan view) of a portion of the first metal layer 140 of the example interposer 111 taken along the line 2-2 associated with the first inset image 136 of FIG. 1. The particular arrangement of metal and carbon nanotube pincushions shown in the illustrated example is for purposes of explanation. Teachings disclosed herein can apply to any other suitable arrangement. Further, although FIG. 2 is described in terms of a cross-sectional top view of the first metal layer 140 of the interposer 111 of FIG. 1, the example structures and associated features detailed herein can be suitably adapted for implementation in the first die 108, the second die 110, the package substrate 112, and/or any other suitable location within the example IC package 100 of FIG. 1.

As shown in the illustrated example of FIG. 2, the first metal layer 140 includes a set of first elongate traces or lines 202 (e.g., bitlines) of metal associated with a VDD network (e.g., a power delivery network). The first metal layer 140 further includes a set of second elongate traces or lines 204 (e.g., bitlines) of metal associated with a VSS network (e.g., a ground network). In the illustrated example of FIG. 2, the different traces 202, 204 correspond to different ones of the first contact pads 118 and the first conductive pad 138 of FIG. 1. These two different sets of traces 202, 204 are each shown with a different shading for purposes of visual distinction. However, in some examples, both sets of traces 202, 204 are made of the same material (e.g., copper) in the same metal layer 140. As shown in the illustrated example, the different first and second traces 202, 204 are arranged in an alternating pattern. In the example of FIG. 2, each trace 202, 204 includes a corresponding series of metal bumps 206 (represented by spaced apart circles) that, in this example, correspond to the interconnects 116 of FIG. 1. In other examples, the circles shown in FIG. 2 can represent other types of interconnects (e.g., the metal vias 160 in the dies 108, 110 of FIG. 1, the metal vias 174 in the interposer 111 of FIG. 1, etc.). In this example, the space along each trace 202, 204 between adjacent pairs of the bumps 206 include different instances of the first array 130 of carbon nanotubes 131. As discussed above, some or all of the first carbon nanotube arrays 130 can be implemented with the structures and/or features of the other carbon nanotube arrays 132, 134 shown and described in connection with the second and/or third inset images 152, 166 of FIG. 1.

Although the first carbon nanotube arrays 130 are shown as being between every pair of adjacent bumps 206, in some examples, the first carbon nanotube arrays 130 may instead be present in fewer areas. For instance, in some examples, the first carbon nanotube arrays 130 can be positioned on the first traces 202 but omitted from the second traces 204. In other examples, the first carbon nanotube arrays 130 can be positioned on the second traces 204 but omitted from the first traces 202. Other arrangements are also possible. In some examples, suitable locations for the first carbon nanotube arrays 130 depend on whether or not the carbon nanotubes 131 are electrically conductive. For instance, if the carbon nanotubes 131 are non-electrically conductive, then the associated first arrays 130 can be located everywhere as shown without fear of current leakage or other unwanted effects. If the carbon nanotubes 131 are electrically conductive, then the arrays 130 can be used only between different portions of the same power network and/or the same signal network unless an insulating layer (e.g., the electrically insulating layer 162 is employed to avoid a short circuit).

FIG. 3 is a cross-sectional top view (e.g., a plan view) of a portion of the third and fourth metal layers 154, 156 of the first semiconductor die 108 taken along the line 3-3 associated with the second inset image 152 of FIG. 1. For purposes of explanation and clarity, the upper metal layer (e.g., the fourth metal layer 156) is shown in dashed lines and illustrated to be see-through so that the underlying material is visible (e.g., the third metal layer 154, the intervening metal vias 160, and the second arrays 132 of carbon nanotubes 131). The particular arrangement of metal and carbon nanotube pincushions shown in the illustrated example is for purposes of explanation, and teachings disclosed herein can apply to any other suitable arrangement. Further, although FIG. 3 is described in terms of a cross-sectional top view of the third and fourth metal layers 154, 156 of the first semiconductor die 108 of FIG. 1, the example structures and associated features detailed herein can be suitably adapted for implementation in the first die 108, the interposer 111, the package substrate 112, and/or any other suitable location within the example IC package 100 of FIG. 1.

As shown in the illustrated example of FIG. 3, the lower metal layer (e.g., the third metal layer 154) includes a set of third elongate traces or lines 302 (e.g., bitlines) of metal associated with a VDD network (e.g., a power delivery network). The third metal layer 154 further includes a set of fourth elongate traces or lines 304 (e.g., bitlines) of metal associated with a VSS network (e.g., a ground network). In a similar manner, the upper metal layer of the illustrated example (e.g., the fourth metal layer 156) includes a set of fifth elongate traces or lines 306 (e.g., bitlines) of metal associated with the VDD network and a set of sixth elongate traces or lines 308 (e.g., bitlines) of metal associated with the VSS network. As shown in the illustrated example, the fifth and sixth traces 306, 308 of the fourth metal layer 156 extend transverse (e.g., perpendicular) to the underlying third and fourth traces 302, 304 of the third metal layer 154. Further, in this example, the vias 160 are positioned at locations where the corresponding traces 302, 306 of the VDD network or the corresponding traces 304, 308 of the VSS network overlap or intersect. That is, as shown in FIG. 3, some of the vias 160 are positioned at locations where the third and fifth traces 302, 306 (associated with the VDD network) overlap, thereby electrically coupling the different portions (e.g., different metal layers) of the VDD network. Likewise, some of the vias 160 are positioned at locations where the fourth and sixth traces 304, 308 (associated with the VSS network) overlap, thereby electrically coupling the different portions (e.g., different metal layers) of the VSS network.

The arrangement of the traces 302, 304, 306, 308 and the vias 160 extending therebetween shown in FIG. 3 results in the VDD and VSS networks being electrically isolated from one another. That said, as shown in FIG. 3, the second carbon nanotube arrays 132 are positioned at the intersections or locations of overlap between the traces 302, 306 associated with the VDD network and the traces 304, 306 associated with the VSS network. To maintain electrical isolation of the two networks, in some such examples, the second carbon nanotube arrays 132 include at least one insulating layer 162 adjacent at least one end of the nanotubes 131, as discussed above. Additionally or alternatively, in some examples, the second carbon nanotube arrays 132 are implemented with electrically non-conductive carbon nanotubes 131. In some such examples, the insulating layer 162 adjacent one or both ends of the nanotubes 131 can be omitted.

In the illustrated example of FIG. 3, the second carbon nanotube arrays 132 are positioned at every overlapping intersection between the traces 302, 306 of the VDD network and the traces 304, 308 of the VSS network. However, in some examples, the second carbon nanotube arrays 132 are distributed more sparsely. In some examples, how densely or sparsely the carbon nanotube arrays 132 are distributed depends on the tradeoff between the benefit of improved thermal conduction provided by the arrays 132 and the drawback of additional electrical parasitics arising from the presence of the arrays 132. Generally speaking, electrical parasitics between the power supply network and the ground network are not a significant concern. Accordingly, as shown in FIG. 3, the tradeoff weighs in favor of a dense distribution of the second arrays 132 positioned at any (e.g., every) suitable location. On the other hand, electrical parasitics are a more significant concern for the performance and/or integrity of signal networks. Accordingly, in some examples, the tradeoff weighs in favor of a relatively sparse distribution of the second arrays 132 at fewer (e.g., limited, isolated) locations where the impact on the signaling will not be a significant concern.

Having different densities of distribution of the second carbon nanotube arrays 132 adjacent to a power delivery network than adjacent to a signaling network is most easily achieved when the power delivery network is separated from the signaling network. That is, in some examples, a higher density of second carbon nanotube arrays 132 is implemented between metal layers of supply and ground networks than is implemented between the metal layers of the signaling network when the semiconductor die 108 is implemented with backside power delivery. The illustrated example of FIG. 3 corresponds to a power grid in a backside power delivery network. By contrast, if the semiconductor die 108 does not include backside power delivery (e.g., both the power delivery and signaling are on the frontside), the close proximity between the power lines and signaling lines within the different metal layers 154, 156 can increase the concern of the effects of leakage current, short circuits, and/or other parasitics arising from the second carbon nanotube arrays 132 even when the arrays are directly coupled to the power delivery lines rather than the signaling lines. In summary, the amount and/or density of distribution of example arrays of carbon nanotubes disclosed herein can be suitably adapted depending on the circumstances in which the arrays are implemented.

The arrangement and/or distribution of the first and second arrays 130, 132 of carbon nanotubes 131 discussed above can be similarly applied and suitably adapted to the arrangement and/or distribution of the third arrays 134 of carbon nanotubes 131 within the interposer 111 as represented in the third inset image 166 of FIG. 1. That is, in some examples, when electrically conductive carbon nanotubes are used, the associated arrays can be positioned between metal layers of the same network with potential limitations on their distribution subject to concerns of the effects of resulting parasitics. In examples where the carbon nanotubes 131 are electrically non-conductive, the associated arrays can be more widely used because there is less concern for creating an electrical short. However, the effects of parasitics (e.g., noise, leakage current, etc.) can still be an important consideration, particularly when the carbon nanotubes 131 are adjacent to signaling lines.

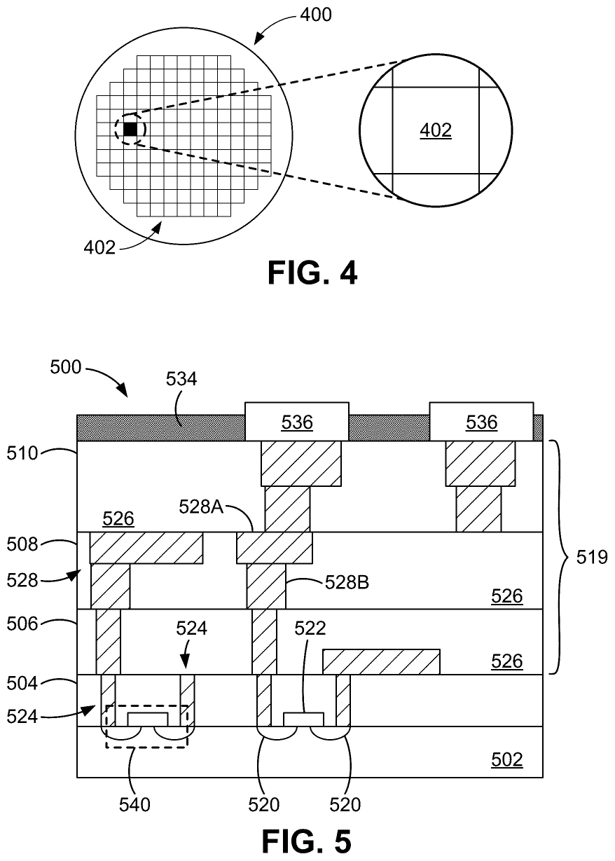

The example carbon nanotube arrays 130, 132, 134 disclosed herein may be included in any suitable electronic component. FIGS. 4-7 illustrate various examples of apparatus that may include the carbon nanotube arrays 130, 132, 134 disclosed herein.

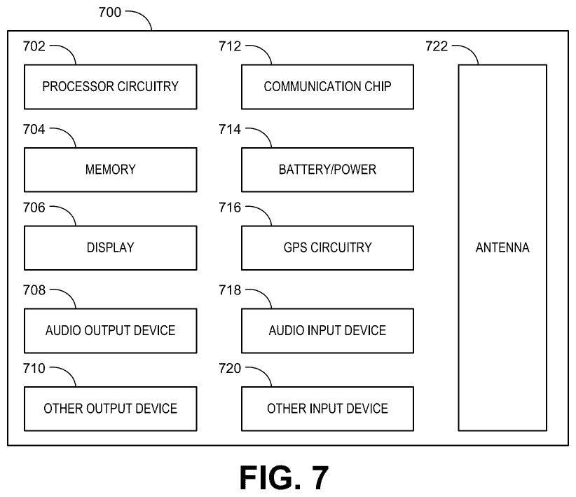

FIG. 4 is a top view of a wafer 400 and dies 402 that may be included in the IC package 100 of FIG. 1 (e.g., as any suitable ones of the dies 108, 110) and that may include one or more carbon nanotube arrays 130, 132, 134 disclosed herein. The wafer 400 includes semiconductor material and one or more dies 402 having circuitry. Each of the dies 402 may be a repeating unit of a semiconductor product. After the fabrication of the semiconductor product is complete, the wafer 400 may undergo a singulation process in which the dies 402 are separated from one another to provide discrete “chips.” The die 402 includes one or more transistors (e.g., some of the transistors 540 of FIG. 5, discussed below), supporting circuitry to route electrical signals to the transistors, passive components (e.g., traces, resistors, capacitors, inductors, and/or other circuitry), and/or any other components. In some examples, the die 402 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 402. For example, a memory array of multiple memory circuits may be formed on a same die 402 as programmable circuitry (e.g., the processor circuitry 702 of FIG. 7) and/or other logic circuitry. Such memory may store information for use by the programmable circuitry. The examples disclosed herein may be manufactured using a die-to-wafer assembly technique in which some dies are attached to a wafer 400 that includes others of the dies, and the wafer 400 is subsequently singulated.

FIG. 5 is a cross-sectional side view of an IC device 500 that may be included in the example IC package 100 (e.g., in any one of the dies 108, 110) and that includes one or more of the example carbon nanotube arrays 130, 132, 134 disclosed herein. One or more of the IC devices 500 may be included in one or more dies 402 (FIG. 4). The IC device 500 may be formed on a die substrate 502 (e.g., the wafer 400 of FIG. 4) and may be included in a die (e.g., the die 402 of FIG. 4). The die substrate 502 may be a semiconductor substrate including semiconductor materials including, for example, n-type or p-type materials systems (or a combination of both). The die substrate 502 may include, for example, a crystalline substrate formed using a bulk silicon or a silicon-on-insulator (SOI) substructure. In some examples, the die substrate 502 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 502. Although a few examples of materials from which the die substrate 502 may be formed are described here, any material that may serve as a foundation for an IC device 500 may be used. The die substrate 502 may be part of a singulated die (e.g., the dies 402 of FIG. 4) or a wafer (e.g., the wafer 400 of FIG. 4).

The IC device 500 may include one or more device layers 504 disposed on and/or above the die substrate 502. The device layer 504 may include features of one or more transistors 540 (e.g., metal oxide semiconductor field-effect transistors (MOSFETs)) formed on the die substrate 502. The device layer 504 may include, for example, one or more source and/or drain (S/D) regions 520, a gate 522 to control current flow between the S/D regions 520, and one or more S/D contacts 524 to route electrical signals to/from the S/D regions 520. The transistors 540 may include additional features not depicted for the sake of clarity, such as device isolation regions, gate contacts, and the like. The transistors 540 are not limited to the type and configuration depicted in FIG. 5 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 540 may include a gate 522 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 540 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 540 along the source-channel-drain direction, the gate electrode may include a U-shaped structure that includes a bottom portion substantially parallel to the surface of the die substrate 502 and two sidewall portions that are substantially perpendicular to the top surface of the die substrate 502. In other examples, at least one of the metal layers that form the gate electrode may be a planar layer that is substantially parallel to the top surface of the die substrate 502 and does not include sidewall portions substantially perpendicular to the top surface of the die substrate 502. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 520 may be formed within the die substrate 502 adjacent to the gate 522 of corresponding transistor(s) 540. The S/D regions 520 may be formed using an implantation/diffusion process or an etching/deposition process, for example. In the former process, dopants such as boron, aluminum, antimony, phosphorous, or arsenic may be ion-implanted into the die substrate 502 to form the S/D regions 520. An annealing process that activates the dopants and causes them to diffuse farther into the die substrate 502 may follow the ion-implantation process. In the latter process, the die substrate 502 may first be etched to form recesses at the locations of the S/D regions 520. An epitaxial deposition process may then be carried out to fill the recesses with material that is used to fabricate the S/D regions 520. In some implementations, the S/D regions 520 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 520 may be formed using one or more alternate semiconductor materials such as germanium or a group III-V material or alloy. In further examples, one or more layers of metal and/or metal alloys may be used to form the S/D regions 520.

Electrical signals, such as power and/or input/output (I/O) signals, may be routed to and/or from the devices (e.g., transistors 540) of the device layer 504 through one or more interconnect layers disposed on the device layer 504 (illustrated in FIG. 5 as interconnect layers 506-2010). For example, electrically conductive features of the device layer 504 (e.g., the gate 522 and the S/D contacts 524) may be electrically coupled with the interconnect structures 528 of the interconnect layers 506-2010. The one or more interconnect layers 506-2010 may form a metallization stack (also referred to as an “ILD stack”) 519 of the IC device 500.

The interconnect structures 528 may be arranged within the interconnect layers 506-2010 to route electrical signals according to a wide variety of designs (in particular, the arrangement is not limited to the particular configuration of interconnect structures 528 depicted in FIG. 5). Although a particular number of interconnect layers 506-2010 is depicted in FIG. 5, examples of the present disclosure include IC devices having more or fewer interconnect layers than depicted.

In some examples, the interconnect structures 528 may include lines 528a and/or vias 528b filled with an electrically conductive material such as a metal. The lines 528a may be arranged to route electrical signals in a direction of a plane that is substantially parallel with a surface of the die substrate 502 upon which the device layer 504 is formed. For example, the lines 528a may route electrical signals in a direction in and/or out of the page from the perspective of FIG. 5. The vias 528b may be arranged to route electrical signals in a direction of a plane that is substantially perpendicular to the surface of the die substrate 502 upon which the device layer 504 is formed. In some examples, the vias 528b may electrically couple lines 528a of different interconnect layers 506-2010 together.

The interconnect layers 506-2010 may include a dielectric material 526 disposed between the interconnect structures 528, as shown in FIG. 5. In some examples, the dielectric material 526 disposed between the interconnect structures 528 in different ones of the interconnect layers 506-2010 may have different compositions; in other examples, the composition of the dielectric material 526 between different interconnect layers 506-2010 may be the same.

A first interconnect layer 506 (referred to as Metal 1 or “M1”) may be formed directly on the device layer 504. In some examples, the first interconnect layer 506 may include lines 528a and/or vias 528b, as shown. The lines 528a of the first interconnect layer 506 may be coupled with contacts (e.g., the S/D contacts 524) of the device layer 504.

A second interconnect layer 508 (referred to as Metal 2 or “M2”) may be formed directly on the first interconnect layer 506. In some examples, the second interconnect layer 508 may include vias 528b to couple the lines 528a of the second interconnect layer 508 with the lines 528a of the first interconnect layer 506. Although the lines 528a and the vias 528b are structurally delineated with a line within each interconnect layer (e.g., within the second interconnect layer 508) for the sake of clarity, the lines 528a and the vias 528b may be structurally and/or materially contiguous (e.g., simultaneously filled during a dual-damascene process) in some examples.

A third interconnect layer 510 (referred to as Metal 3 or “M3”) (and additional interconnect layers, as desired) may be formed in succession on the second interconnect layer 508 according to similar techniques and/or configurations described in connection with the second interconnect layer 508 or the first interconnect layer 506. In some examples, the interconnect layers that are “higher up” in the metallization stack 519 in the IC device 500 (i.e., further away from the device layer 504) may be thicker.

The IC device 500 may include a solder resist material 534 (e.g., polyimide or similar material) and one or more conductive contacts 536 formed on the interconnect layers 506-2010. In FIG. 5, the conductive contacts 536 are illustrated as taking the form of bond pads. The conductive contacts 536 may be electrically coupled with the interconnect structures 528 and configured to route the electrical signals of the transistor(s) 540 to other external devices. For example, solder bonds may be formed on the one or more conductive contacts 536 to mechanically and/or electrically couple a chip including the IC device 500 with another component (e.g., a circuit board). The IC device 500 may include additional or alternate structures to route the electrical signals from the interconnect layers 506-2010; for example, the conductive contacts 536 may include other analogous features (e.g., posts) that route the electrical signals to external components.

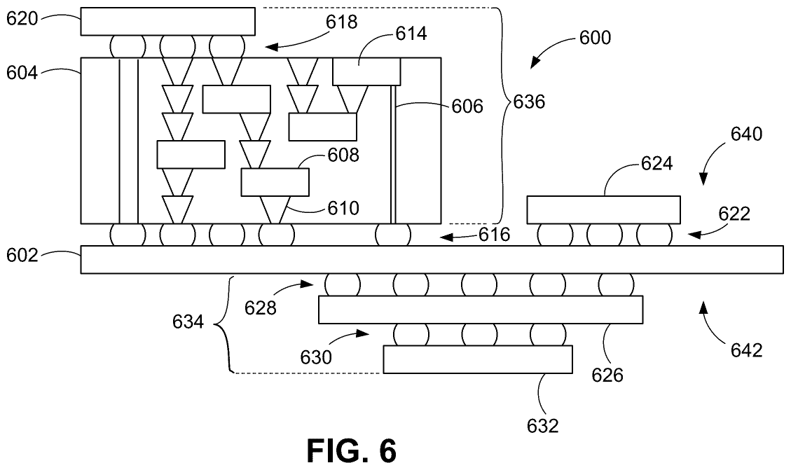

FIG. 6 is a cross-sectional side view of an IC device assembly 600 that may include one or more of the example carbon nanotube arrays 130, 132, 134 disclosed herein. In some examples, the IC device assembly corresponds to the IC package 100. The IC device assembly 600 includes a number of components disposed on a circuit board 602 (which may be, for example, a motherboard). The IC device assembly 600 includes components disposed on a first face 640 of the circuit board 602 and an opposing second face 642 of the circuit board 602; generally, components may be disposed on one or both faces 640 and 642. Any of the IC packages discussed below with reference to the IC device assembly 600 may take the form of the example IC package 100 of FIG. 1.

In some examples, the circuit board 602 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 602. In other examples, the circuit board 602 may be a non-PCB substrate.

The IC device assembly 600 illustrated in FIG. 6 includes a package-on-interposer structure 636 coupled to the first face 640 of the circuit board 602 by coupling components 616. The coupling components 616 may electrically and mechanically couple the package-on-interposer structure 636 to the circuit board 602, and may include solder balls (as shown in FIG. 6), male and female portions of a socket, an adhesive, an underfill material, and/or any other suitable electrical and/or mechanical coupling structure.

The package-on-interposer structure 636 may include an IC package 620 coupled to an interposer 604 by coupling components 618. The coupling components 618 may take any suitable form for the application, such as the forms discussed above with reference to the coupling components 616. Although a single IC package 620 is shown in FIG. 6, multiple IC packages may be coupled to the interposer 604; indeed, additional interposers may be coupled to the interposer 604. The interposer 604 may provide an intervening substrate used to bridge the circuit board 602 and the IC package 620. The IC package 620 may be or include, for example, a die (the die 402 of FIG. 4), an IC device (e.g., the IC device 500 of FIG. 5), or any other suitable component. Generally, the interposer 604 may spread a connection to a wider pitch or reroute a connection to a different connection. For example, the interposer 604 may couple the IC package 620 (e.g., a die) to a set of BGA conductive contacts of the coupling components 616 for coupling to the circuit board 602. In the example illustrated in FIG. 6, the IC package 620 and the circuit board 602 are attached to opposing sides of the interposer 604; in other examples, the IC package 620 and the circuit board 602 may be attached to a same side of the interposer 604. In some examples, three or more components may be interconnected by way of the interposer 604.

In some examples, the interposer 604 may be formed as a PCB, including multiple metal layers separated from one another by layers of dielectric material and interconnected by electrically conductive vias. In some examples, the interposer 604 may be formed of an epoxy resin, a fiberglass-reinforced epoxy resin, an epoxy resin with inorganic fillers, a ceramic material, or a polymer material such as polyimide. In some examples, the interposer 604 may be formed of alternate rigid or flexible materials that may include the same materials described above for use in a semiconductor substrate, such as silicon, germanium, and other group III-V and group IV materials. The interposer 604 may include metal interconnects 608 and vias 610, including but not limited to through-silicon vias (TSVs) 606. The interposer 604 may further include embedded devices 614, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 604. The package-on-interposer structure 636 may take the form of any of the package-on-interposer structures known in the art.

The IC device assembly 600 may include an IC package 624 coupled to the first face 640 of the circuit board 602 by coupling components 622. The coupling components 622 may take the form of any of the examples discussed above with reference to the coupling components 616, and the IC package 624 may take the form of any of the examples discussed above with reference to the IC package 620.

The IC device assembly 600 illustrated in FIG. 6 includes a package-on-package structure 634 coupled to the second face 642 of the circuit board 602 by coupling components 628. The package-on-package structure 634 may include a first IC package 626 and a second IC package 632 coupled together by coupling components 630 such that the first IC package 626 is disposed between the circuit board 602 and the second IC package 632. The coupling components 628, 630 may take the form of any of the examples of the coupling components 616 discussed above, and the IC packages 626, 632 may take the form of any of the examples of the IC package 620 discussed above. The package-on-package structure 634 may be configured in accordance with any of the package-on-package structures known in the art.

FIG. 7 is a block diagram of an example electrical device 700 that may include one or more of the example carbon nanotube arrays 130, 132, 134 disclosed herein. For example, any suitable ones of the components of the electrical device 700 may include one or more of the device assemblies 600, IC devices 500, or dies 402 disclosed herein, and may be arranged in the example IC package 100 that includes one or more of the example carbon nanotube arrays 130, 132, 134. A number of components are illustrated in FIG. 7 as included in the electrical device 700, but any one or more of these components may be omitted or duplicated, as suitable for the application. In some examples, some or all of the components included in the electrical device 700 may be attached to one or more motherboards. In some examples, some or all of these components are fabricated onto a single system-on-a-chip (SoC) die.

Additionally, in various examples, the electrical device 700 may not include one or more of the components illustrated in FIG. 7, but the electrical device 700 may include interface circuitry for coupling to the one or more components. For example, the electrical device 700 may not include a display 706, but may include display interface circuitry (e.g., a connector and driver circuitry) to which a display 706 may be coupled. In another set of examples, the electrical device 700 may not include an audio input device 718 (e.g., microphone) or an audio output device 708 (e.g., a speaker, a headset, earbuds, etc.), but may include audio input or output device interface circuitry (e.g., connectors and supporting circuitry) to which an audio input device 718 or audio output device 708 may be coupled.

The electrical device 700 may include programmable circuitry 702 (e.g., one or more processing devices). The programmable circuitry 702 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 700 may include a memory 704, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 704 may include memory that shares a die with the programmable circuitry 702. This memory may be used as cache memory and may include embedded dynamic random access memory (eDRAM) or spin transfer torque magnetic random access memory (STT-MRAM).

In some examples, the electrical device 700 may include a communication chip 712 (e.g., one or more communication chips). For example, the communication chip 712 may be configured for managing wireless communications for the transfer of data to and from the electrical device 700. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 712 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 712 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 712 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 712 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 712 may operate in accordance with other wireless protocols in other examples. The electrical device 700 may include an antenna 722 to facilitate wireless communications and/or to receive other wireless communications (such as AM or FM radio transmissions).

In some examples, the communication chip 712 may manage wired communications, such as electrical, optical, or any other suitable communication protocols (e.g., the Ethernet). As noted above, the communication chip 712 may include multiple communication chips. For instance, a first communication chip 712 may be dedicated to shorter-range wireless communications such as Wi-Fi or Bluetooth, and a second communication chip 712 may be dedicated to longer-range wireless communications such as global positioning system (GPS), EDGE, GPRS, CDMA, WiMAX, LTE, EV-DO, or others. In some examples, a first communication chip 712 may be dedicated to wireless communications, and a second communication chip 712 may be dedicated to wired communications.

The electrical device 700 may include battery/power circuitry 714. The battery/power circuitry 714 may include one or more energy storage devices (e.g., batteries or capacitors) and/or circuitry for coupling components of the electrical device 700 to an energy source separate from the electrical device 700 (e.g., AC line power).

The electrical device 700 may include a display 706 (or corresponding interface circuitry, as discussed above). The display 706 may include any visual indicators, such as a heads-up display, a computer monitor, a projector, a touchscreen display, a liquid crystal display (LCD), a light-emitting diode display, or a flat panel display.

The electrical device 700 may include an audio output device 708 (or corresponding interface circuitry, as discussed above). The audio output device 708 may include any device that generates an audible indicator, such as speakers, headsets, or earbuds.

The electrical device 700 may include an audio input device 718 (or corresponding interface circuitry, as discussed above). The audio input device 718 may include any device that generates a signal representative of a sound, such as microphones, microphone arrays, or digital instruments (e.g., instruments having a musical instrument digital interface (MIDI) output).

The electrical device 700 may include GPS circuitry 716. The GPS circuitry 716 may be in communication with a satellite-based system and may receive a location of the electrical device 700, as known in the art.

The electrical device 700 may include any other output device 710 (or corresponding interface circuitry, as discussed above). Examples of the other output device 710 may include an audio codec, a video codec, a printer, a wired or wireless transmitter for providing information to other devices, or an additional storage device.

The electrical device 700 may include any other input device 720 (or corresponding interface circuitry, as discussed above). Examples of the other input device 720 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 700 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 700 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time +1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that improve the dissipation of heat within and/or from integrated circuit packages using carbon nanotubes. Unlike known IC packages that primarily rely on thermal conduction through the metallization layers and associated metal vias extending between the layers, examples disclosed herein include arrays of carbon nanotubes extending between different metallization layers to facilitate the transfer of heat through and/or throughout an IC package. Such carbon nanotube arrays can be implemented within a semiconductor die (e.g., an IC chip) within a package, within an interposer and/or a package substrate supporting the semiconductor die, and/or at an interface between one or more of the semiconductor die, the interposer, and/or the package substrate. The improved thermal dissipation made possible by the arrays of carbon nanotubes implemented in examples disclosed herein allows for the fabrication of IC packages with improved performance and/or efficiency. Disclosed systems, apparatus, articles of manufacture, and methods are accordingly directed to one or more improvement(s) in the operation of a machine such as a computer or other electronic and/or mechanical device.

Further examples and combinations thereof include the following:

Example 1 includes an integrated circuit package comprising a first metal layer, a second metal layer, and an array of carbon nanotubes extending from the first metal layer toward the second metal layer.

Example 2 includes the integrated circuit package of example 1, including an interposer including the first metal layer, and a semiconductor die attached to the interposer, the semiconductor die including the second metal layer.

Example 3 includes the integrated circuit package of example 2, including a plurality of bumps electrically coupling the interposer and the semiconductor die, the array of carbon nanotubes between two adjacent ones of the bumps.

Example 4 includes the integrated circuit package of example 1, including a dielectric layer between the first metal layer and the second metal layer, the array of carbon nanotubes extending through an opening in the dielectric layer, the array of carbon nanotubes more thermally conductive than the dielectric layer to facilitate dissipation of heat.

Example 5 includes the integrated circuit package of example 4, including an interposer, the first metal layer, the dielectric layer, and the second metal layer included in the interposer.

Example 6 includes the integrated circuit package of example 4, including a semiconductor die, the first metal layer, the dielectric layer, and the second metal layer included in the semiconductor die.

Example 7 includes the integrated circuit package of example 4, further including a package substrate, the first metal layer, the dielectric layer, and the second metal layer included in the package substrate.

Example 8 includes the integrated circuit package of any one of examples 1-7, wherein the carbon nanotubes are electrically non-conductive.

Example 9 includes the integrated circuit package of any one of examples 1-7, wherein the carbon nanotubes are electrically conductive.

Example 10 includes the integrated circuit package of example 9, including a non-conductive cap between the array of carbon nanotubes and the second metal layer.

Example 11 includes the integrated circuit package of any one of examples 1-10, including a metal cap between the array of carbon nanotubes and the second metal layer.

Example 12 includes the integrated circuit package of any one of examples 1-11, including a seed layer between the array of carbon nanotubes and the first metal layer, the seed layer including nickel.

Example 13 includes the integrated circuit package of any one of examples 1-12, including an adhesive material between the array of carbon nanotubes and the first metal layer.

Example 14 includes the integrated circuit package of any one of examples 1-13, wherein the carbon nanotubes are orientated substantially perpendicular to the first and second metal layers.

Example 15 includes an apparatus comprising a first metal layer, a second metal layer, an interconnect electrically coupling the first metal layer and the second metal layer, and carbon nanotubes between the first and second metal layers, the carbon nanotubes adjacent to the interconnect to transfer heat between the first and second metal layers.

Example 16 includes the apparatus of example 15, wherein the carbon nanotubes are electrically coupled to a first portion of the first metal layer, and the interconnect is electrically coupled to a second portion of the first metal layer, the second portion of the first metal layer electrically isolated from the first portion of the first metal layer.

Example 17 includes the apparatus of any one of examples 15 or 16, wherein the carbon nanotubes are electrically coupled to a first portion of the first metal layer, and the interconnect is electrically coupled to a second portion of the first metal layer, the second portion of the first metal layer electrically coupled to the first portion of the first metal layer.

Example 18 includes an apparatus comprising a first layer of metal in an integrated circuit package, a second layer of metal in the integrated circuit package, and an array of carbon nanotubes to thermally couple the first and second layers, the first and second layers electrically coupled independent of the array of carbon nanotubes.

Example 19 includes the apparatus of example 18, wherein the first and second layers are associated with at least one of a power supply network or a ground network.

Example 20 includes the apparatus of example 18, wherein the first and second layers are associated with a signaling network.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An integrated circuit package comprising:
a first metal layer;
a second metal layer; and
an array of carbon nanotubes extending from the first metal layer toward the second metal layer.

2. The integrated circuit package of claim 1, including:
an interposer including the first metal layer; and
a semiconductor die attached to the interposer, the semiconductor die including the second metal layer.

3. The integrated circuit package of claim 2, including a plurality of bumps electrically coupling the interposer and the semiconductor die, the array of carbon nanotubes between two adjacent ones of the bumps.

4. The integrated circuit package of claim 1, including a dielectric layer between the first metal layer and the second metal layer, the array of carbon nanotubes extending through an opening in the dielectric layer, the array of carbon nanotubes more thermally conductive than the dielectric layer to facilitate dissipation of heat.

5. The integrated circuit package of claim 4, including an interposer, the first metal layer, the dielectric layer, and the second metal layer included in the interposer.

6. The integrated circuit package of claim 4, including a semiconductor die, the first metal layer, the dielectric layer, and the second metal layer included in the semiconductor die.

7. The integrated circuit package of claim 4, further including a package substrate, the first metal layer, the dielectric layer, and the second metal layer included in the package substrate.

8. The integrated circuit package of claim 1, wherein the carbon nanotubes are electrically non-conductive.

9. The integrated circuit package of claim 1, wherein the carbon nanotubes are electrically conductive.

10. The integrated circuit package of claim 9, including a non-conductive cap between the array of carbon nanotubes and the second metal layer.

11. The integrated circuit package of claim 1, including a metal cap between the array of carbon nanotubes and the second metal layer.

12. The integrated circuit package of claim 1, including a seed layer between the array of carbon nanotubes and the first metal layer, the seed layer including nickel.

13. The integrated circuit package of claim 1, including an adhesive material between the array of carbon nanotubes and the first metal layer.

14. The integrated circuit package of claim 1, wherein the carbon nanotubes are orientated substantially perpendicular to the first and second metal layers.

15. An apparatus comprising:
a first metal layer;
a second metal layer;
an interconnect electrically coupling the first metal layer and the second metal layer; and
carbon nanotubes between the first and second metal layers, the carbon nanotubes adjacent to the interconnect to transfer heat between the first and second metal layers.

16. The apparatus of claim 15, wherein the carbon nanotubes are electrically coupled to a first portion of the first metal layer, and the interconnect is electrically coupled to a second portion of the first metal layer, the second portion of the first metal layer electrically isolated from the first portion of the first metal layer.

17. The apparatus of claim 15, wherein the carbon nanotubes are electrically coupled to a first portion of the first metal layer, and the interconnect is electrically coupled to a second portion of the first metal layer, the second portion of the first metal layer electrically coupled to the first portion of the first metal layer.

18. An apparatus comprising:
a first layer of metal in an integrated circuit package;
a second layer of metal in the integrated circuit package; and
an array of carbon nanotubes to thermally couple the first and second layers, the first and second layers electrically coupled independent of the array of carbon nanotubes.

19. The apparatus of claim 18, wherein the first and second layers are associated with at least one of a power supply network or a ground network.

20. The apparatus of claim 18, wherein the first and second layers are associated with a signaling network.
